(19) United States
(12) Patent Application Publication
(10) Pub. No.: US 2023/0006120 A1
(43) Pub. Date: Jan. 5, 2023

(54) LIGHT EMITTING DIODE MODULE AND LIGHT-EMITTING DIODE MODULE INSPECTION METHOD

(71) Applicant: SAMSUNG ELECTRONICS CO., LTD., Suwon-si (KR)

(72) Inventors: Youngki JUNG, Suwon-si (KR); Sangmin SHIN, Suwon-si (KR); Donghun LEE, Suwon-si (KR); Chulgyu JUNG, Suwon-si (KR)

(73) Assignee: SAMSUNG ELECTRONICS CO., LTD., Suwon-si (KR)

(21) Appl. No.: 17/903,253

(22) Filed: Sep. 6, 2022

Related U.S. Application Data
(63) Continuation of application No. PCT/KR2021/002746, filed on Mar. 5, 2021.

(30) Foreign Application Priority Data
Mar. 6, 2020 (KR) 10-2020-0028320

(51) Int. Cl. H01L 33/62; H01L 33/38; G01R 31/26; H01L 25/075

(52) U.S. Cl. CPC H01L 33/62; H01L 33/382; G01R 31/2635; H01L 25/0753

(57) ABSTRACT

A light emitting diode (LED) module includes a substrate layer including an active area and a non-active area excluding the active area, at least one wiring layer provided on the substrate layer, and a test pad connected to the at least one wiring layer and provided in the non-active area.

### CROSS-REFERENCE TO RELATED APPLICATION(S)

This application is a by-pass continuation of International Application No. PCT/KR2021/002746, filed on Mar. 5, 2021, in the Korean Intellectual Property Receiving Office, which is based on and claims priority to Korean Patent Application No. 10-2020-0028320, filed on Mar. 6, 2020, in the Korean Intellectual Property Office, the disclosures of which are incorporated by reference herein in their entireties.

### BACKGROUND

### 1. Field

The present disclosure relates to a light emitting diode module configured to display an image using a light emitting diode, and a light emitting diode module inspection method.

### 2. Description of Related Art

A display apparatus converts electrical information into visual information and displays the visual information. The display apparatus may include a television and a monitor and further include a portable device such as a laptop personal computer (PC), a smart phone, or a tablet PC.

The display apparatus may include a non-self-emissive display panel such as a liquid crystal display (LCD), and a self-emissive display panel that generates light corresponding to a data signal.

Particularly, a light emitting diode (LED) has been actively studied for implementing the self-emissive display panel. The LED is a device for converting an electrical signal into the form of light such as infrared rays and visible light, by using the characteristics of compound semiconductors. The LED is used for home appliances, remote controls, electronic displays, and a variety of automation devices. In addition, the LED has been widely used for small hand-held electronic devices and large-size display apparatuses.

A micro-light emitting diode (micro-LED or uLED) display panel is one of flat display panels and is composed of a plurality of inorganic light emitting diodes (inorganic LEDs) that is 100 micrometers or less. In comparison with the LCD panel requiring a backlight, a micro-LED panel may offer better contrast, response times, and energy efficiency. Both organic light emitting diodes (OLEDs) and micro-LEDs corresponding to inorganic light emitting devices have good energy efficiency. However, the micro-LED has higher brightness and emission efficiency, and longer lifetime than the OLED.

### SUMMARY

Provided are a light emitting diode (LED) module and an LED module inspection method capable of providing an efficient and high-quality product by detecting an error in each manufacturing operation in a manufacturing process of the LED module.

Additional aspects will be set forth in part in the description which follows and, in part, will be apparent from the description, or may be learned by practice of the presented embodiments.

According to an aspect of the disclosure, an LED module may include a substrate layer including an active area and a non-active area excluding the active area, at least one wiring layer provided on the substrate layer, and a test pad connected to the at least one wiring layer and provided in the non-active area.

The LED module may further include an LED provided on an upper side of the substrate layer and configured to emit light toward the substrate layer, and the at least one wiring layer may be connected to the LED.

The LED module may further include a plurality of upper electrodes provided on an upper side of the LED and connected to the LED.

The LED module may further include an upper insulating layer provided on at least one of the plurality of upper electrodes; and a film on glass (FOG) electrode provided on an upper side of the upper insulating layer.

According to an aspect of the disclosure, an LED module may include a substrate layer including a cutting surface and an active area, at least one wiring layer provided on the substrate layer, an LED provided on an upper side of the substrate layer and configured to emit light toward the substrate layer, a plurality of upper electrodes provided on an upper side of the LED and connected to the LED, and an upper insulating layer provided on at least one of the plurality of upper electrodes; and a film on glass (FOG) electrode provided on an upper side of the upper insulating layer, wherein the cutting surface is formed by cutting a predetermined boundary between the active area and a test pad.

The cutting surface may be formed through grinding after cutting the test pad.

The cutting surface may include a test line cutting surface to which the at least one wiring layer and the test pad are connected.

The LED module may further include a protective coating structure corresponding to the cutting surface.

According to an aspect of the disclosure, an LED module inspection method, where the LED module includes a plurality of layers, may include laminating at least one layer among the plurality of layers on a substrate, obtaining a test current from a test pad connected to at least one wiring layer provided on the LED module, and determining whether an error is generated in the LED module, based on the test current. The substrate may include an active area and a non-active area excluding the active area, and the test pad may be provided in an area of the substrate opposite to the active area.

The determining whether an error is generated in the LED module may include identifying a capacitance of the LED module based on the test current, and determining whether an error is generated in the LED module based on the capacitance.

The determining whether an error is generated in the LED module may be performed based on a test current that is obtained before mounting an LED.

The LED module may further include an LED provided on an upper side of the substrate and configured to emit light toward the substrate, and the determining whether an error is generated in the LED module may be performed based on a light emission of the LED corresponding to the test current obtained after mounting the LED.

The method may include cutting a predetermined boundary between the active area and the test pad, and, after cutting the predetermined boundary, grinding a cutting surface formed by cutting the predetermined boundary.

The method may include, after cutting the predetermined boundary, providing a protective coating structure corresponding to the cutting surface.

The method may include, before cutting the predetermined boundary, removing a test line connecting the at least one wiring layer to the test pad.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a view illustrating an exterior of a display apparatus according to an embodiment;

FIG. 2 is a diagram illustrating a configuration of a light emitting diode (LED) module according to an embodiment;

FIG. 3 is a diagram illustrating a sub-pixel circuit provided in a sub-pixel region of the LED module of FIG. 2 according to an embodiment;

FIGS. 4A and 4B are plan views illustrating the LED module according to an embodiment;

FIGS. 5, 6, 7 and 8 are side views illustrating the LED module according to an embodiment;

FIG. 9 is a view illustrating an operation of cutting a substrate of the LED module according to an embodiment;

FIG. 10 is a view illustrating a cutting surface and a grinding operation of the cutting surface according to an embodiment;

FIG. 11 is a view illustrating a structure of a protective coating corresponding to the cutting surface according to an embodiment; and

FIG. 12 is a view illustrating an operation of removing a test line according to an embodiment.

### DETAILED DESCRIPTION

In the following description, like reference numerals refer to like elements throughout the specification. Well-known functions or constructions are not described in detail since they would obscure the one or more exemplar embodiments with unnecessary detail. Terms such as “unit”, “module”, “member”, and “block” may be embodied as hardware or software. According to embodiments, a plurality of “unit”, “module”, “member”, and “block” may be implemented as a single component or a single “unit”, “module”, “member”, and “block” may include a plurality of components.

It will be understood that when an element is referred to as being “connected” another element, it can be directly or indirectly connected to the other element, wherein the indirect connection includes “connection via a wireless communication network”.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

It will be understood that, although the terms first, second, third, etc., may be used herein to describe various elements, but is should not be limited by these terms. These terms are only used to distinguish one element from another element.

As used herein, the singular forms “a,” “an” and “the” are intended to include the plural forms as well, unless the context clearly indicates otherwise.

An identification code is used for the convenience of the description but is not intended to illustrate the order of each step. The each step may be implemented in the order different from the illustrated order unless the context clearly indicates otherwise.

Reference will now be made in detail to embodiments of the disclosure, examples of which are illustrated in the accompanying drawings.

A light emitting diode (LED) module and an LED module inspection method may provide an efficient and high-quality product by detecting an error in each manufacturing operation in a manufacturing process of the LED module.

A display module may be applied and installed in a wearable device, a portable device, a handheld device, and electronic products or electric apparatuses that need various displays, as a single unit, and further a plurality of the display modules may be assembled in a matrix type and applied to a display apparatus such as a monitor for a personal computer, a high-resolution TV, a signage, an electronic display, and the like.

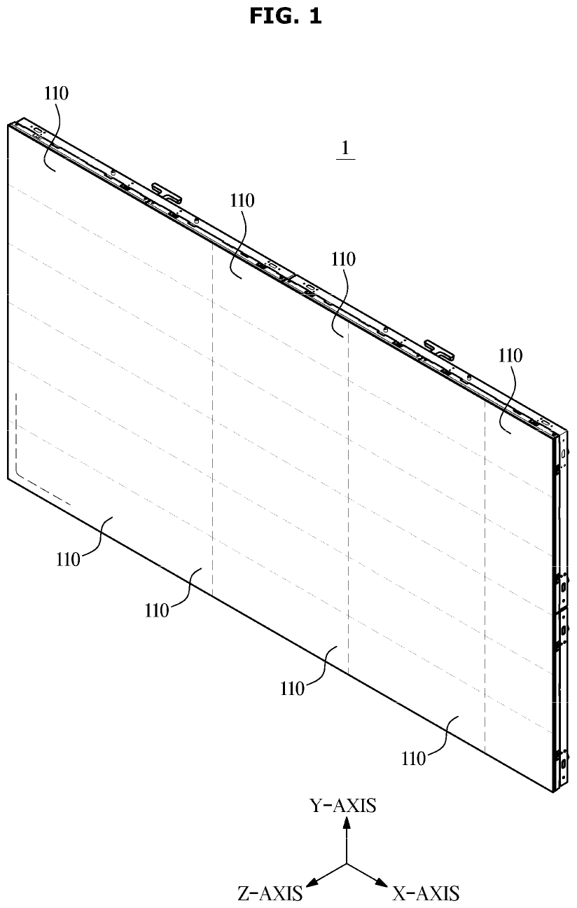

FIG. 1 is a view illustrating an exterior of a display apparatus according to an embodiment.

X-axis, Y-axis, and Z-axis perpendicular to each other are indicated in FIG. 1. The X-axis direction represents the left-right direction, the Y-axis direction represents the up-down direction, and the Z-axis direction represents the front-rear direction.

A display apparatus 1 is a device that displays information, material, data, etc. as characters, figures, graphs, images, etc. The display apparatus 1 may be implemented as a digital advertising display, an electronic display, a screen, a television, and a monitor. The display apparatus may be installed on a wall or a ceiling, or may be installed on an indoor or outdoor ground by a stand.

The display apparatus 1 may include an LED module 110 provided to display an image, and a frame 21 coupled to a rear side of the LED module 110 so as to support the LED module 110.

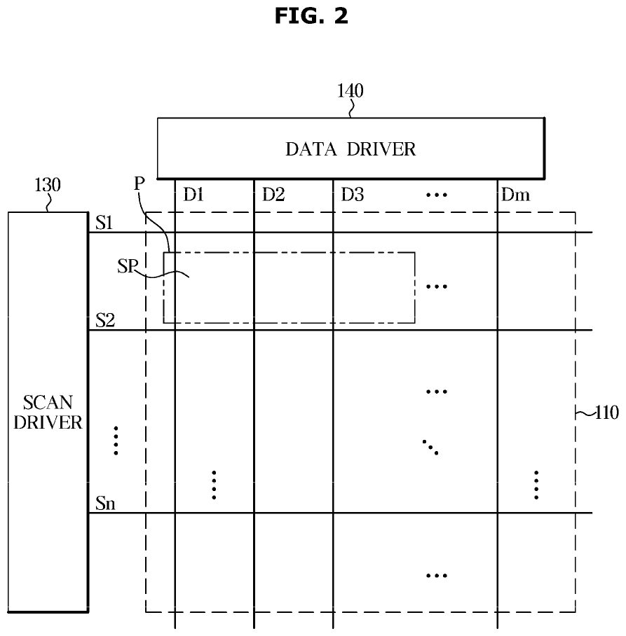

FIG. 2 is a diagram illustrating a configuration of an LED module according to an embodiment.

Referring to FIG. 2, a plurality of data lines D1-Dm arranged in a column direction, a plurality of scan lines S1-Sn arranged in a row direction, and a plurality of sub-pixel regions SP arranged adjacent to an intersection between the data line D1-Dm and the scan line S1-Sn may be provided on one surface of the LED module 110. A sub-pixel circuit may be provided in each sub-pixel region SP. At least three sub-pixel regions SP adjacent to each other among the plurality of sub-pixel regions SP may form a pixel region P.

The data lines D1-Dm may transmit a data signal representing an image signal to sub-pixel circuits in the sub-pixel regions SP, and the scan lines S1-Sn may transmit a scan signal to sub-pixel circuits in the sub-pixel regions SP.

By a scan driver 130, the scan signal may be sequentially applied to each of the plurality of scan lines S1-Sn, and by a data driver 140, a data voltage corresponding to the image signal may be applied to the plurality of data lines D1-Dm.

According to one embodiment of the present disclosure, the scan driver 130 and the data driver 140 may be mounted on an upper side of a substrate 111 of the LED module. Accordingly, a bezel (a width in a lateral direction surrounding the pixel region) of the LED module 110 may be minimized or omitted and thus an entire front surface of the LED module 110 may operate as the pixel region.

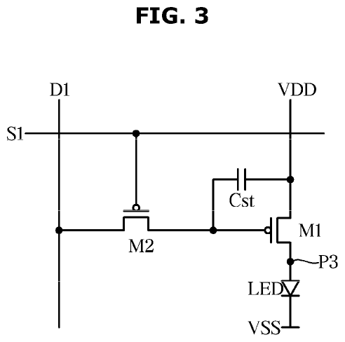

FIG. 3 is a diagram illustrating a sub-pixel circuit provided in a sub-pixel region of the LED module of FIG. 2 according to an embodiment.

FIG. 3 is an equivalent circuit diagram illustrating the sub-pixel circuit of the sub-pixel region SP of FIG. 2. Particularly, FIG. 3 illustrates the sub-pixel circuit driven by a first scan line S1 and a first data line D1.

Referring to FIG. 3, the sub-pixel circuit may include an LED, two transistors M1 and M2, and a capacitor Cst. The plurality of transistors M1 and M2 may be provided as PMOS transistors. However, such a circuit configuration is merely an example of the sub-pixel circuit. Therefore, the sub-pixel circuit is not limited to the circuit configuration of FIG. 3.

As for a switching transistor M2, a gate electrode may be connected to the scan line Sn. A source electrode may be connected to the data line Dm. A drain electrode may be connected to one end of the capacitor Cst and a gate electrode of a driver transistor M1. The other end of the capacitor Cst may be connected to a power voltage VDD. As for the driver transistor M1, a source electrode may be connected to the power voltage VDD. A drain electrode may be connected to an anode 310 of the LED, a cathode 320 of the LED may be connected to a reference voltage VSS and thus the LED may emit light based on a current applied from the driver transistor M1.

The reference voltage VSS connected to the cathode 320 of the LED may be less than the power voltage VDD and thus a ground voltage may be used as the reference voltage VSS.

An operation of the sub-pixel circuit is as follows. First, when the scan signal is applied to the scan line Sn and the switching transistor M2 is turned on, the data voltage may be transmitted to one end of the capacitor Cst and the gate electrode of the driver transistor M1. As a result, a gate-source voltage VGS of the driver transistor M1 may be maintained for a predetermined period of time, by the capacitor Cst. In addition, the driver transistor M1 may allow the LED to emit light by applying a current ILED corresponding to the gate-source voltage VGS of the driver transistor M1 to the anode 310 of the LED.

In response to a high data voltage VDATA being transmitted to the gate electrode of the driver transistor M1, the gate-source voltage VGS of the driver transistor M1 may be reduced. Accordingly, a small amount of current ILED may be applied to the anode 310 of the LED and thus the LED may emit less light. Therefore, the LED may display a low gradation. On the other hand, in response to a low data voltage VDATA being transmitted, the gate-source voltage VGS of the driver transistor M1 may be increased. Accordingly, a large amount of current ILED may be applied to the anode 310 of the LED and thus the LED may emit more light. Therefore, the LED may display a high gradation. Thus, a level of data voltage VDATA applied to each sub-pixel circuits may be determined based on an image to be displayed.

Referring to FIG. 3, a wiring layer of the LED module according to one embodiment may be connected to P3 to determine whether an error is generated in the LED module.

Particularly, at least one wiring layer provided in the LED module may be connected to P3 in which the wiring and the diode are connected.

The wiring layer may be connected to a test pad provided on the substrate to be described later.

The test pad may correspond to pad provided in a remaining part of an active module of the LED module, and may obtain a current for detecting whether an error is generated in the LED module.

Particularly, while layers are laminated in the manufacturing process of the LED, a user may supply power to the LED module through the VDD.

The user may obtain a current of the test pad connected through P3 and the wiring layer.

The user may determine the error of the LED module based on the current flowing through the test pad. Details related to this will be described later.

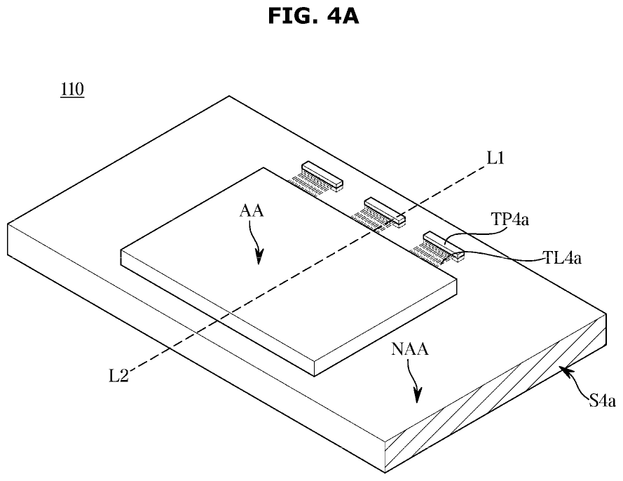

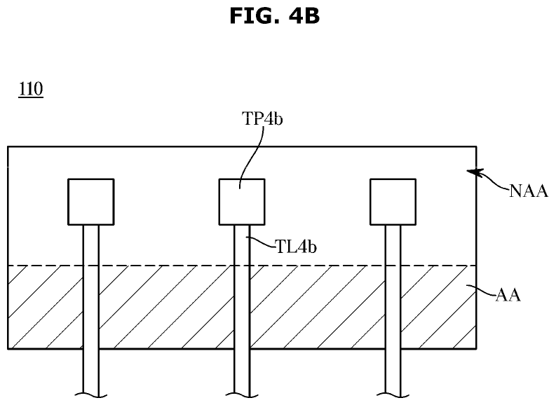

FIGS. 4A and 4B are plan views illustrating the LED module according to an embodiment.

Particularly, FIG. 4A is a perspective view of the LED module, and FIG. 4B is a plan view of the LED module.

Referring to FIGS. 4A and 4B, the LED module may include a substrate layer S4a. The LED module may be provided by laminating a plurality of layers of an active area AA provided on the substrate.

In the LED module, a portion, in which an LED is mounted and the LED emits light, may be defined as an active area AA.

The AA may represent an area including a wiring layer needed for driving a diode device, in addition to the diode device.

Further, the substrate S4a may include a non-active area NAA that is a region other than active area AA.

The non-active area NAA may represent an area excluding the active area provided in the LED.

Test pads TP4a and TP4b according to one embodiment may be provided in the non-active area NAA of the LED module.

Particularly, the LED may include a wiring that is a data line, a power line, and a line for a control signal.

In the LED module, the test pad and test lines TL4a and TL4b may be provided outside the active area. The test line may be connected to a signal wiring layer of the LED.

A coating for protecting the line may be provided during a following process of the manufacture of the LED module.

A shape of the LED module shown in FIGS. 4A and 4B is only one embodiment of the present disclosure, and the shape of the LED module is not limited thereto.

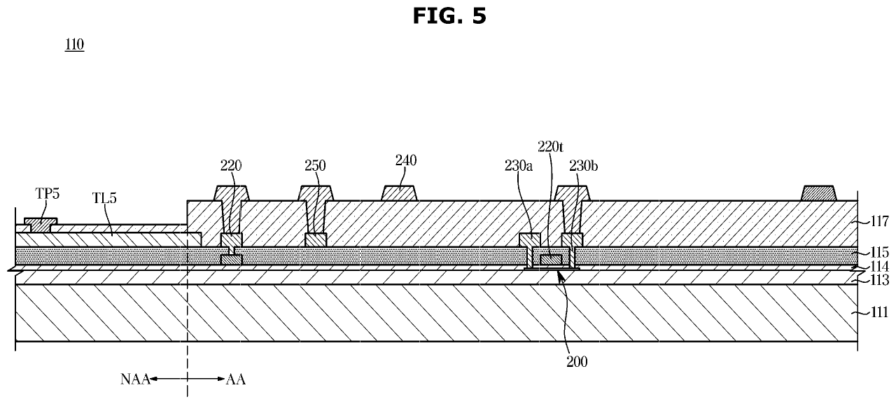

FIGS. 5, 6, 7 and 8 are side views illustrating the LED module according to an embodiment.

FIGS. 5 to 8 are views illustrating cross-sections L1 and L2 of FIG. 4A.

As shown in FIG. 5, the substrate 111 is prepared, and a light absorption layer 112 is provided on the substrate 111.

The substrate 111 may include various materials. For example, the substrate 111 may be formed of a transparent glass material containing SiO2 as a main component, but the substrate 111 is not limited thereto. Therefore, the substrate 111 may be formed of transparent plastic material and thus the substrate 111 may have flexibility. The plastic material may be an organic material selected from a group consisting of polyethersulphone (PES), polyacrylate (PAR), polyetherimide (PEI), polyethyelenenaphthalate (PEN), polyethylene terephthalate (PET), polyphenylene sulfide (PPS), polyallylate, polyimide, polycarbonate (PC), cellulose triacetate (TAC), and cellulose acetate propionate (CAP).

According to one embodiment of the present disclosure, the LED module 110 is a bottom emission type, and the substrate 111 may be formed of a transparent material.

The substrate 111 may include an emission region L1 in which an LED 380 is arranged to emit light, and a non-emission region L2 in which circuit elements such as a thin film transistor (TFT) 200 are arranged and light is not emitted. A light absorption layer provided to absorb external light to improve visibility may be provided on the non-emission region L2 of the substrate 111.

The above-described LED may be provided as an inorganic LED.

Particularly, the LED 380 may be an LED of 10-100 μm size, and the LED 380 may be formed in such a way that a thin film growth method is performed with inorganic materials such as Al, Ga, N, P, As and In, on a sapphire substrate or a silicon substrate and then the sapphire substrate or the silicon substrate is cut out and separated.

The light absorption layer may include a black inorganic material, a black organic material, or a black metal that absorb light well.

For example, a light absorbing material may include carbon black, polyene-based pigment, azo-based pigment, azomethine-based pigment, diimmonium-based pigment, phthalocyanine-based pigment, quinone-based pigment, indigo-based pigment, thioindigo-based pigment, dioxadin-based pigment, quinacridone-based pigment, isoindolinone-based pigment, metal oxides, metal complexes, and other materials such as aromatic hydrocarbons.

As show in FIG. 5, a buffer layer 113 may be provided on the substrate 111. The buffer layer 113 may provide a flat surface on the upper side of the substrate 111, and may prevent foreign matter or moisture from penetrating through the substrate 111. For example, the buffer layer 113 may be formed of an inorganic material such as silicon oxide, silicon nitride, silicon oxynitride, aluminum oxide, aluminum nitride, titanium oxide or titanium nitride, or an organic material such as polyimide, polyester, or acryl, or may be formed with a laminated body in which a plurality of materials among the exemplified materials is laminated.

Referring to FIG. 5, the LED module according to one embodiment may include a signal wiring layer.

The signal wiring layer is a TFT substrate, and a thin film transistor and various wirings for driving an LED device 300 may be provided in the pixel region P of the upper surface.

The TFT forming the TFT substrate is not limited to a specific structure or type. That is, the TFTs cited in the present disclosure include oxide TFTs and Si TFTs (poly silicon, a-silicon) other than Low-temperature polycrystalline silicon (LTPS) TFT. Alternatively, it is possible to apply P type (or N-type) MOSFET formed in a Si wafer CMOS process.

In response to the TFT being turned on, a driving signal input from the outside through the wiring may be applied to the LED device 300 and thus the LED device 300 may emit light, thereby realizing an image.

The signal wiring layer, to which a gate electrode 220, a data electrode 250 and the LED are connected may be provided on a first insulating layer 117 and a second insulating layer 118. Test pads TP5, TP6, TP7, and TP8 may be connected to the above-described signal wiring layer through test lines TL5, TL6, TL7, and TL8.

The test line may be provided in a structure including a line protective coating as well as the line itself.

Based on the test pad TP5 being provided as described above, the user can detect an error of the LED.

The user may determine a capacitance of the LED module based on a test current obtained through the test pad by using a tester before the diode is mounted on the diode module.

Further, the user may determine whether an error is generated in the LED module based on the obtained capacitance.

Particularly, in response to the capacitance of the diode module, in which only the substrate layer is provided, exceeding a predetermined range, it may be determined that an error is generated in the substrate of the diode module.

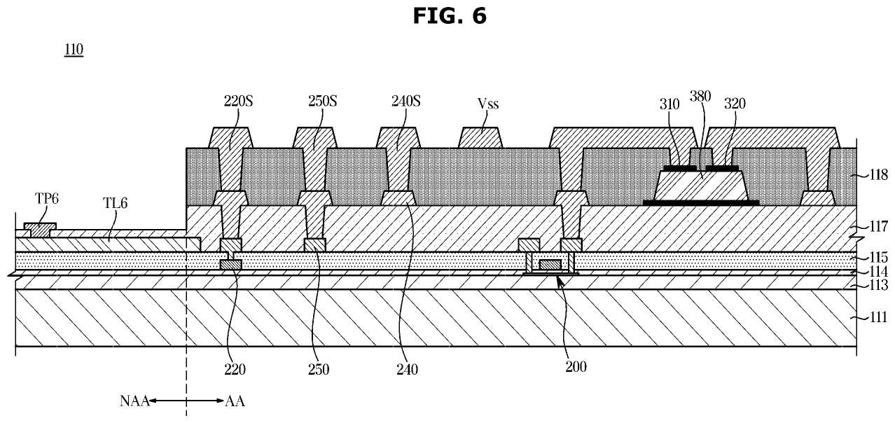

Referring to FIG. 6, the TFT 200 and the LED 380 may be provided on the buffer layer 113.

The transistor 200 may include a semiconductor active layer 210, a gate electrode 220, a source electrode 230a, and a drain electrode 230b. The semiconductor active layer 210 may include a semiconductor material, and may include a source region, a drain region, and a channel region between the source and drain regions. The gate electrode 220 may be provided on the active layer 210 to correspond to the channel region. The source electrode 230a and the drain electrode 230b may be electrically connected to the source region and the drain region of the active layer 210, respectively.

A gate insulating layer 114 may be arranged between the active layer 210 and the gate electrode 220. The gate insulating layer 114 may be formed of an inorganic insulating material.

An interlayer insulating layer 115 may be arranged between the gate electrode 220 and the source electrode 230a and between the gate electrode 220 and the drain electrode 230b. The interlayer insulating layer 115 may be formed of an organic insulating material or an inorganic insulating material, and may be provided by alternating the organic insulating material and the inorganic insulating material. The first insulating layer 117 as a planarization layer may be arranged on the source electrode 230a and the drain electrode 230b. The first insulating layer 117 may be formed of an organic insulating material or an inorganic insulating material, and may be provided by alternating the organic insulating material and the inorganic insulating material.

According to one embodiment of the present disclosure, the TFT 200 is implemented in a top gate type in which the gate electrode 220 is arranged on top of the semiconductor active layer 210, but is not limited thereto. Therefore, the gate electrode 220 may be arranged below the semiconductor active layer 210.

As shown in FIG. 6, the LED 380 may be arranged on the first insulating layer 117. According to one embodiment of the present disclosure, the LED 380 may be a micro-LED. Micro may refer to a size of 1 to 100 μm, but the present disclosure is not limited thereto. Therefore, the LED 380 may employ an LED that is greater or less than the size of 1 to 100 μm.

The LED 380 may be individually or multiply picked up from a wafer by a transfer mechanism and transferred to the substrate 111. The micro-LED is formed of an inorganic material, and thus the micro-LED may provide a faster reaction rate, low power consumption and high luminance in comparison with an organic LED (OLED) using an organic material. In addition, because the OLED is vulnerable to exposure to moisture and oxygen, the OLED requires an encapsulation process and has poor durability. However, the micro-LED does not require an encapsulation process and has excellent durability.

The LED 380 may emit light of a predetermined wavelength within a wavelength range from ultraviolet (UV) light to visible light. For example, the LED 380 may be a red, green, blue, white LED or UV LED. That is, a red LED, a green LED, and a blue LED are respectively arranged in the adjacent sub-pixel regions SP, and the three adjacent sub-pixel regions SP may form one pixel region P. One color may be determined by mixing red light, green light, and blue light generated in one pixel region P.

The LED 380 may include a p-n diode, the anode 310 and the cathode 320. The anode 310 and/or the cathode 320 may be formed of a variety of conductive materials, including metals, conductive oxides and conductive polymers. The anode 310 may be electrically connected to a signal electrode 510, and the cathode 320 may be electrically connected to a common electrode 530. The p-n diode may include a p-doped portion in the anode 310 side, one or more quantum well and a n-doped portion in the cathode 320 side. Alternatively, a doped portion in the cathode 320 side may correspond to the p-doped portion, and a doped portion in the anode 310 side may correspond to the n-doped portion.

The anode 310 and the cathode 320 may be located on an upper surface of the LED 380. Conversely, a light emitting surface of the LED 380 may be located on a lower surface of the LED 380. Accordingly, the light emitting surface 380 of the LED 380 may be in contact with the first insulating layer 117, and the LED 380 may emit light toward the substrate 111.

The gate electrode 220 and the data electrode 250 may be provided on the first insulating layer 117. A wiring structure in which the gate electrode 220, the data electrode 250 and the LED are connected may be provided on the first insulating layer 117 and the second insulating layer 118.

That is, according to one embodiment of the present disclosure, the LED 380 may be a bottom emission type. Because the LED 380 is a bottom emission type, the pixel circuit element such as the TFT 200 and the LED 380 are arranged so as not to overlap each other in the up-down direction. The LED 380 may be fixed on the first insulating layer 117 by an adhesive coating.

As shown in FIG. 6, the second insulating layer 118 may be provided on the first insulating layer 117 to surround the LED 380. The second insulating layer 118 may include an organic insulating material. For example, the second insulating layer 118 may be formed of acrylic, polymethyl methacrylate (PMMA), benzocyclobutene (BCB), polyimide, acrylate, epoxy, polyester, or the like, but is not limited thereto.

Upper electrodes 220s, 250s, 240s, and Vss may connect various driver ICs 900 configured to drive the LED module 110 to the pixel circuit.

For example, the upper electrodes 220s, 250s, 240s, and Vss may be provided in connection with a power voltage electrode 240, the data electrode 250, the gate electrode 220, and the reference voltage VSS.

The upper electrodes 220s, 250s, 240s, and Vss may include the signal electrode 510 provided to connect the drain electrode 230b of the TFT 200 to the anode 310 of the LED 380 so as to apply a data signal to the LED 380, and the common ground electrode 530 provided to connect the cathode 320 of the LED 380 to the reference voltage VSS: 554 to provide a ground to the LED 380.

Because the LED 380 is a bottom emission type, the first insulating layer 117, the interlayer insulating layer 115, the gate insulating layer 114, and the buffer layer 113 may all be formed of a transparent material.

FIG. 6 illustrates that the LED is transferred and then the second insulating layer is provided, but the form, in which the second insulating layer is provided and then the LED is transferred, may be allowed. In preparing the second insulator and the LED on the substrate, the sequence may vary, and the wiring shape may also vary according to the sequence.

The user may determine whether an error is generated in the LED module based on the light emission of the LED corresponding to the test current obtained from the test pad TP6 after the LED is mounted.

Particularly, in response to a current being applied to the LED module, each LED 380 may operate. On the other hand, in response to a defect occurring in the LED module, the LED 380 may not emit light.

The user may determine that an error is generated in the LED module.

In this case, after the LED is transferred and the signal wiring layer is prepared, lighting evaluation may be performed through a tester.

Thereafter, the repair of the defective pixel of the LED may be performed.

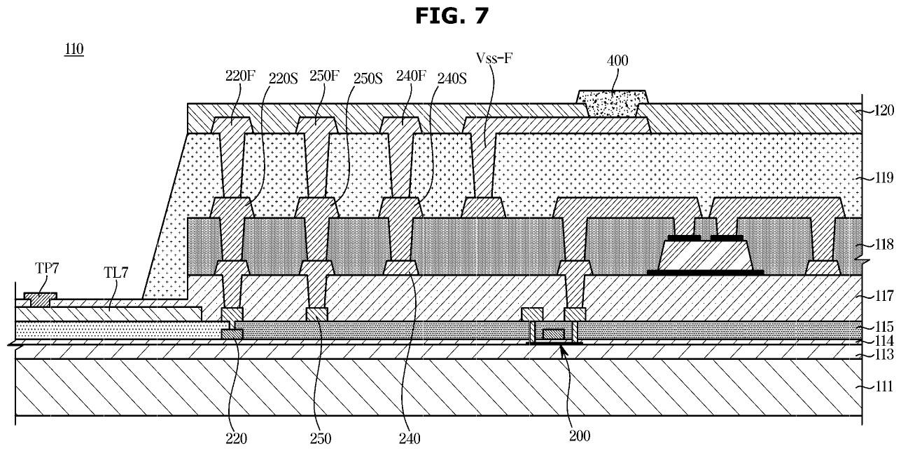

Referring to FIG. 7, the above-described upper electrode may be provided on an upper insulating layer 119, and the upper insulating layer 119 may further include fan-out lines 220F, 250F, 240F, and Vss-F connected to the upper electrode.

The upper insulating layer 119 may be provided to protect the LED while providing the wiring structure connected to the diode and the fan-out lines 220F, 250F, 240F, Vss-F in different layer structures.

In addition, via holes corresponding to the upper electrode 220s, 250s, 240s, and Vss may be provided in the upper insulating layer 119 to provide the fan-out lines 220F, 250F, 240F, and Vss-F.

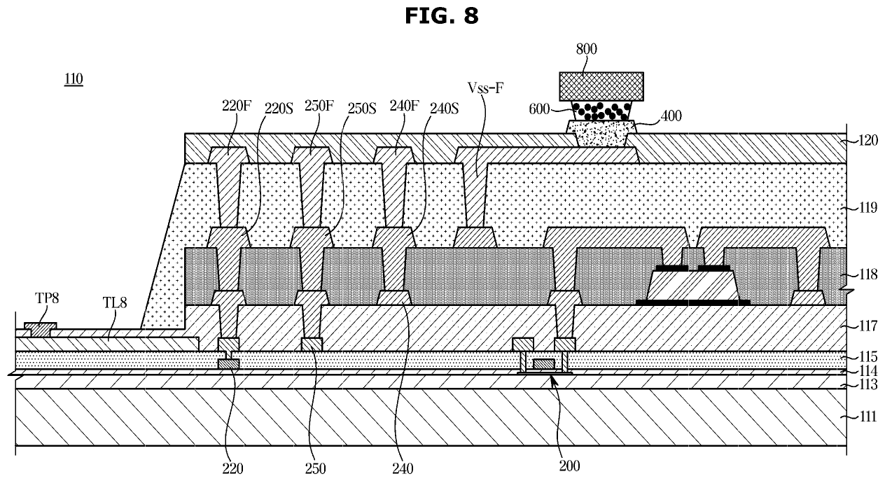

Referring to FIG. 8, a third insulating layer 120 may be provided on the upper insulating layer 119 to be connected to a film on glass (FOG) electrode 800 through the fan-out line and a capping metal 400. According to one embodiment, the capping metal 400 may be formed of Indium Tin Oxide (ITO).

The capping metal 400 may be connected to the FOG electrode 800 through an anisotropic conductive film (ACF) bonding 600.

Various driver integrated circuit (IC) chip, such as a power line, a data IC, a gate IC, a touch sensing IC, a wireless controller, and a communication IC, configured to drive the LED module 110 may be connected to the FOG electrode 800.

The FOG electrode 800 may be electrically connected to the fan-out lines 220F, 250F, 240F, and VssF through the ACF bonding 600.

By the above structure, the driver IC 900 may be arranged on the rear side of the light emitting surface of the substrate 111.

Further, at least one light absorbing layer (black matrix) may be provided in the layers described with reference to FIGS. 5 to 8, so as to improve the uniformity of screen output and color separation through pixel-to-pixel separation.

Based on the test current obtained through the test pads TL7 and TL8 prepared as described above, the user may detect the error of the LED.

The embodiment described with reference to FIGS. 5 to 8 is merely an example of the embodiments of the present disclosure. Therefore, the form in which the LED module is implemented may be the flip chip type and the vertical chip type, but the form of the LED is not limited thereto.

Further, the embodiment described with reference to FIGS. 5 to 8 is merely an example of the embodiments of the present disclosure, and the flip chip type, in which a pair of electrodes are formed in the same direction and a light emission direction is opposite to the direction in which the electrodes are formed, is described as an example of the LED module. However, the vertical chip type, in which a pair of electrodes are formed in opposite directions to each other, may be employed as the LED module, but the type of the LED module is not limited thereto.

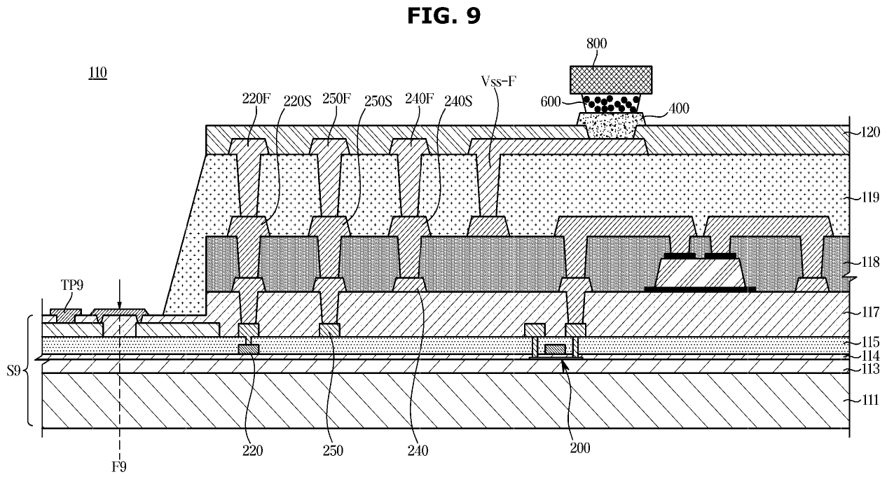

FIG. 9 is a view illustrating an operation of cutting a substrate of the LED module according to an embodiment.

Referring again to FIGS. 5 to 8, the user can produce the LED module by the above-described method, and in response to the completion of the production of the LED module, the user can cut a substrate S9 including the above-described test pad TP9.

Particularly, in cutting the substrate S9, an unnecessary part of the product may be cut by wheel cutting or laser cutting.

In order to avoid cut damage, the substrate S9 may be cut slightly larger than the product size.

Based on the above-described operation, the substrate may include a cutting surface F9, and the cutting surface F9 may be provided by cutting a predetermined boundary between the active area and a test pad provided in the area of the substrate.

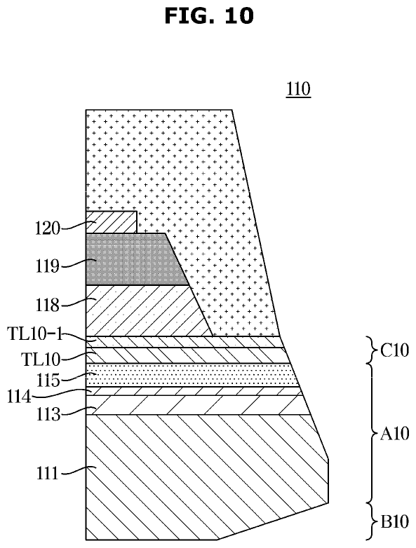

FIG. 10 is a view illustrating a cutting surface and a grinding operation of the cutting surface according to an embodiment.

Referring to FIG. 10, the above-described cutting surface may be provided by grinding the test pad after cutting.

The grinding may be provided to include a cutting surface of the test line TL10 to which at least one signal wiring layer and the test pad are connected.

The test line may be provided as the test line itself TL10 and a line protective coating TL10-1 protecting the test line.

Particularly, the test pad may be connected to the signal wiring layer of the LED module.

Accordingly, in response to cutting between the active area and the non-active area, a cutting surface of the test line connecting the test pad and the signal wiring layer may be included therebetween.

The cutting surface may be ground in the manufacture of the LED module.

Particularly, it is possible to precisely control the size of the active area of the LED module through the grinding.

Further, the production may be completed through chamfering of the LED module through the grinding.

Referring to FIG. 10, the test line and the line protective coating TL10 and TL10-1 are exposed on one surface of the substrate C10, and chamfering is performed on the rear surface of the substrate.

The chamfering is not performed on an area A10 between the test line and the rear surface.

The boundary between the active area and the non-active area including the test pad described in FIG. 10 is only an exemplary embodiment of the present disclosure, and the shape of the cutting surface is not limited thereto.

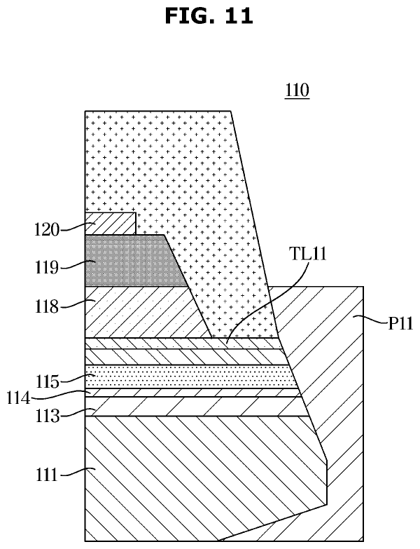

FIG. 11 is a view illustrating a structure of a protective coating corresponding to the cutting surface according to an embodiment.

Referring to FIG. 11, a protective coating structure may be provided to correspond to the cutting surface formed by cutting the predetermined boundary.

FIG. 11 illustrates a state in which test line is not removed before cutting. In this case, because the test line TL11 is not removed, the cutting surface of the line may be exposed on the cutting surface.

The protective coating structure P11 may be provided to correspond to the cutting surface in the manufacturing process of the LED.

The protective coating structure P11 may protect the test line.

The protective coating structure P11 may be processed to minimize a step difference from the surface of the glass substrate.

In addition, for the visibility, the protective coating structure may be formed of a material having a refractive index similar to that of the substrate.

In the present disclosure, the substrate 111 of the LED module may include glass.

Accordingly, as for preparing the protective coating structure P11 corresponding to the cutting surface, the user may provide a protective coating structure having a refractive index similar to that of glass included in the substrate.

However, as will be described later, in the state in which the test line is removed before cutting, the line is not exposed and thus the protective coating structure is not required even when the active area and the non-active area are cut. Details related to this will be described in detail below.

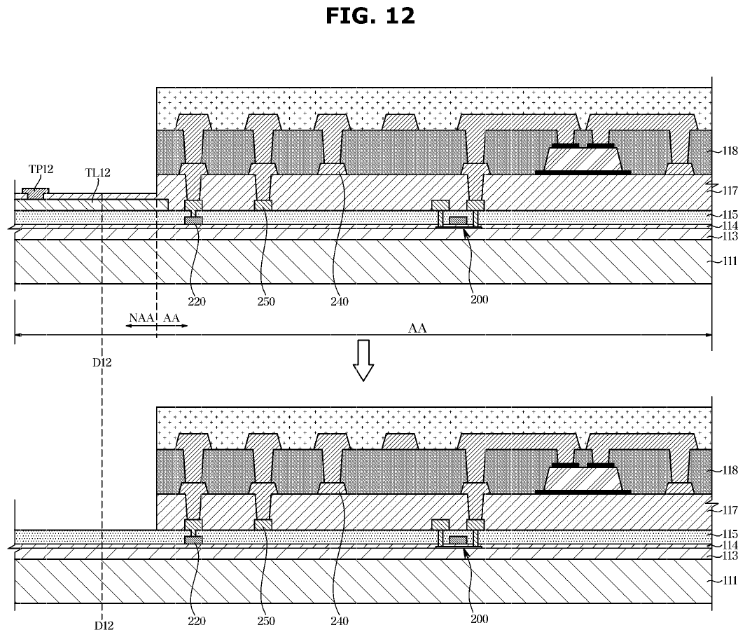

FIG. 12 is a view illustrating an operation of removing a test line according to an embodiment.

Referring to FIG. 12, a user may cut the non-active area NAA including the test line TL12 after the layer structure of the LED module is completed.

The user may remove the test line and a test line protective coating TC12 before cutting the non-active area in the manufacturing process of the LED module.

A predetermined boundary D12 may be identified between the active area AA and the test pad.

Particularly, a masking pattern may be provided in the removal of the line.

The user may remove the test line protective coating TC12 and the test line TL12 by using the masking pattern.

A shape of the predetermined boundary D12 may vary as long as the predetermined boundary D12 is provided between the active area AA and the test pad TP12.

In the state in which the test line TL12 is removed before cutting the substrate based on the above-described operation, the test line may be not exposed on the cutting surface of the substrate, and thus a separate protective coating structure may not be provided in the manufacturing process of the LED.

The operation of grinding of the cutting surface without removing the test line and the operation of cutting the substrate after removing the test line described in FIGS. 10 to 12 are only one embodiment of the present disclosure, and the operation is not limited thereto.

While the present disclosure has been particularly described with reference to exemplary embodiments, it should be understood by those of skilled in the art that various changes in form and details may be made without departing from the spirit and scope of the present disclosure.

What is claimed is:

1. A light emitting diode (LED) module comprising:
a substrate layer comprising an active area and a non-active area excluding the active area;
at least one wiring layer provided on the substrate layer; and
a test pad connected to the at least one wiring layer and provided in the non-active area.

2. The LED module of claim 1, further comprising an LED provided on an upper side of the substrate layer and configured to emit light toward the substrate layer,
wherein the at least one wiring layer is connected to the LED.

3. The LED module of claim 2, further comprising a plurality of upper electrodes provided on an upper side of the LED and connected to the LED.

4. The LED module of claim 3, further comprising:
an upper insulating layer provided on at least one of the plurality of upper electrodes; and
a film on glass (FOG) electrode provided on an upper side of the upper insulating layer.

5. A light emitting diode (LED) module comprising:
a substrate layer comprising a cutting surface and an active area;
at least one wiring layer provided on the substrate layer;
an LED provided on an upper side of the substrate layer and configured to emit light toward the substrate layer;
a plurality of upper electrodes provided on an upper side of the LED and connected to the LED;
an upper insulating layer provided on at least one of the plurality of upper electrodes; and
a film on glass (FOG) electrode provided on an upper side of the upper insulating layer,
wherein the cutting surface is formed by cutting a predetermined boundary between the active area and a test pad.

6. The LED module of claim 5, wherein the cutting surface is formed through grinding after cutting the test pad.

7. The LED module of claim 5, wherein the cutting surface comprises a test line cutting surface to which the at least one wiring layer and the test pad are connected.

8. The LED module of claim 5, further comprising a protective coating structure corresponding to the cutting surface.

9. A light emitting diode (LED) module inspection method, the LED module comprising a plurality of layers, the LED module inspection method comprising:
laminating at least one layer among the plurality of layers on a substrate;
obtaining a test current from a test pad connected to at least one wiring layer provided on the LED module; and
determining whether an error is generated in the LED module, based on the test current,
wherein the substrate comprises an active area and a non-active area excluding the active area, and
wherein the test pad is provided in an area of the substrate opposite to the active area.

10. The LED module inspection method of claim 9, wherein the determining whether the error is generated in the LED module comprises:
identifying a capacitance of the LED module based on the test current; and
determining whether the error is generated in the LED module based on the capacitance.

11. The LED module inspection method of claim 10, wherein the determining whether the error is generated in the LED module is performed before mounting an LED.

12. The LED module inspection method of claim 9, wherein the LED module further comprises an LED provided on an upper side of the substrate and configured to emit light toward the substrate, and
wherein the determining whether the error is generated in the LED module is performed based on a light emission of the LED corresponding to the test current obtained after mounting the LED.

13. The LED module inspection method of claim 9, further comprising:
cutting a predetermined boundary between the active area and the test pad; and
after cutting the predetermined boundary, grinding a cutting surface formed by cutting the predetermined boundary.

14. The LED module inspection method of claim 13, further comprising after cutting the predetermined boundary, providing a protective coating structure corresponding to the cutting surface.

15. The LED module inspection method of claim 14, further comprising before cutting the predetermined boundary, removing a test line connecting the at least one wiring layer to the test pad.
